(19) United States
(12) Patent Application Publication
(10) Pub. No.: US 2025/0098512 A1
(43) Pub. Date: Mar. 20, 2025

(54) SUCTION UNIT, METHOD OF CONTROLLING THE SAME AND METHOD OF MANUFACTURING DISPLAY DEVICE USING THE SAME

(71) Applicant: Samsung Display Co., LTD., Yongin-si (KR)

(72) Inventors: Jong-Hee LIM, Yongin-si (KR); Jaeil KIM, Yongin-si (KR); Hak-Min KIM, Yongin-si (KR); Hyoung-Joo KIM, Yongin-si (KR); Jin Pyung LEE, Yongin-si (KR); Eun Su JUN, Yongin-si (KR); Il Young JEONG, Yongin-si (KR); Sang Sun HAN, Yongin-si (KR)

(21) Appl. No.: 18/787,845

(22) Filed: Jul. 29, 2024

(30) Foreign Application Priority Data
Sep. 19, 2023 (KR) 10-2023-0124977

(51) Int. Cl. H10K 71/00; B23K 26/082; B23K 26/142; B23K 26/38

(52) U.S. Cl. CPC H10K 71/851; B23K 26/0821; B23K 26/142; B23K 26/38

(57) ABSTRACT

A suction unit control method includes simulating an air flow about a suction port, through which fumes generated when a laser beam is radiated on a target substrate on a stage unit to cut the target substrate are sucked up, installing an air blower on three or four sides around a laser cutting end at a height close to the suction port, controlling on and off of first to fourth solenoid valves of the air blower based on a movement of the stage unit while performing laser cutting on the target substrate while moving the stage unit.

This application claims priority to Korean Patent Application No. 10-2023-0124977, filed on Sep. 19, 2023, and all the benefits accruing therefrom under 35 U.S.C. § 119, the content of which in its entirety is herein incorporated by reference.

### BACKGROUND

### (a) Field

Embodiments of the invention relate to a suction unit, a control method thereof, and a system and method for manufacturing a display device using the suction unit. More specifically, embodiments of the invention relate to a suction unit capable of controlling fumes generated when laser cutting is performed while a stage unit of a laser cutting equipment moves, a control method thereof, and a system and method for manufacturing a display device using the suction unit.

### (b) Description of the Related Art

The importance of display devices is increasing with the development of multimedia.

Accordingly, various types of display devices such as an organic light emitting display (OLED) and a liquid crystal display (LCD) are widely used in various fields.

The display panel constituting the display device may be formed by cutting a cell-level substrate formed from a mother substrate, and fine particles or fumes may be generated during the substrate cutting process.

Fine particles or fumes generated during a cutting process may be adsorbed to a pad portion and cause poor contact of the pad portion.

Recently, a system and method for manufacturing a display device that can effectively remove fumes that may be generated during the substrate cutting process has been developed.

### SUMMARY

Conventionally, for example, in Korean Patent Application No. 2020-0048601, a suction cup may be formed around the panel according to the panel cutting shape of the display device, and fumes may be removed through the suction hole formed on the outer edge of the suction cup according to the cutting shape while the positions of the panel and the suction cup are fixed during laser cutting.

However, in this case, when the stage on which the panel is installed moves, the distance between the laser cutting position and the suction port increases, such that a decrease in suction power may occur, and contamination of the upper optical system may occur when the suction power decreases.

In addition, since the display device panel may include adhesive components, the fumes generated when cutting the panel also contains adhesive components, which blocks the suction port and reduces suction performance.

Accordingly, embodiments of the invention provide a system and method for manufacturing a display device that can effectively remove fumes that may be generated during the substrate cutting process that performed while a stage is moved.

A system for manufacturing a display device according to an embodiment of the invention includes a main body which is open on upper and lower sides and forms an internal space through which a laser beam from an optical system is radiated to a target substrate, an exhaust passage provided between an upper surface of a lower plate of the main body, an inner surface of an outer box of the main body, and an outer surface of an inner cup of the main body surrounding a cutting line of the target substrate, a stage unit on which the target substrate is placed, where the stage unit moves in way such that the laser beam is radiated along the cutting line of the target substrate which moves with the stage unit, a suction unit which suctions fumes generated during laser beam irradiation processing on the target substrate while moving the stage unit, and a control unit which controls a setting value of the suction unit based on a moving speed of the stage unit and a moving direction of the stage unit.

A method of manufacturing a display device according to an embodiment of the invention includes controlling an on and off operation time of an air blower based on a movement of a stage unit, where an inlet, through which fumes generated by a target substrate processed by laser beam radiation are sucked up, and a hovering forming portion through which the fumes are allowed to hover therein are disposed in an inner space of a main body, through which a laser beam is radiated, and the air blower is disposed between the inlet and the inner space in the main body to form an air to flow through the inlet.

A suction unit according to an embodiment of the invention includes a suction port connected to an exhaust passage, an air blower which forms an airflow to move fumes generated when cutting a target substrate by radiating a laser beam toward the suction port, wherein the air blower is disposed at a lower part of a main body which is close to the suction port between the suction port and an inner space of the main body through which the laser beam is radiated, and a control unit which controls the air blower in a way such that the fumes are sucked into the suction port in response to a moving speed of the stage unit and a moving direction of the stage unit.

In an embodiment, the suction port may include an expansion hole formed open across an inner cup forming the main body and an outer box, a guide portion inclined upward and outward at an edge of the expansion hole, and an eddy forming portion extending from the guide part, wherein the eddy forming portion forms an eddy of the fumes sucked through the expansion hole by negative pressure generated when a dust collection unit connected to the exhaust passage operates.

A method of controlling a suction unit according to an embodiment of the invention includes simulating an airflow about a suction port, through which fumes generated when a laser beam is radiated on a target substrate on a stage unit to cut the target substrate are sucked up, installing an air blower on three or four sides around a laser cutting end at a height close to the suction port, and controlling on and off of first to fourth solenoid valves of the air blower based on a movement of the stage unit while performing laser cutting on the target substrate while moving the stage unit.

In an embodiment, the method may further include selectively controlling the on and off of the first to fourth solenoid valves of the air blower and adjusting a spraying position and a spraying angle of a nozzle of the air blower, controlling a pipe pressure of first and second connection pipes, which are connected to a dust collection unit, by controlling pipe control valves of the first and second connection pipes, and storing on-off operation and time data of the first to fourth solenoid valves in response to a moving speed and a moving direction of the stage unit, where the simulating an airflow comprises adjusting the on and off of the first to fourth solenoid valves, the spray angle, an air pressure of the air blower, and the pipe pressure of the first and second connection pipes based on a movement of the fumes by the stage unit.

In an embodiment, the method may further include optimizing on-off operation and time setting values of the first to fourth solenoid valves of the air blower, and creating a setting based on the optimized setting values of the air blower for the target substrate.

According to the system and method for manufacturing a display device according to an embodiment of the invention, the quality and improvement of the display device are secured by controlling the fumes generated when moving the stage on which the panel of the display device is placed in the laser cutting device of the display device.

According to the system and method for manufacturing a display device according to an embodiment of the invention, it is possible to prevent equipment contamination due to fume movement by stage movement, for example, contamination of the exterior or optical system, based on air flow simulation.

According to the system and method for manufacturing the display device according to an embodiment of the invention, clogging of the intake port by fumes containing adhesive components can be minimized through optimal design of the intake port, thereby increasing the maintenance period of the suction unit.

According to the system and method for manufacturing a display device according to an embodiment of the invention, the on and off operation of a plurality of air blowers disposed on all sides of the suction unit are controlled, and the operation is turned on and off at a time based on the laser cutting line length for each target substrate model, while the setting values can be fed back into a setting by linking the setting values with the movement of the stage unit.

### BRIEF DESCRIPTION OF THE DRAWINGS

FIG. 1 is a plan view of a system for manufacturing a display device according to an embodiment of the invention.

FIG. 2 is a cross-sectional view taken along line I-I of FIG. 1.

FIG. 3 is a cross-sectional view taken along line II-II in FIG. 1.

FIG. 4A is a diagram showing a system for manufacturing a display device according to another embodiment of the invention.

FIG. 4B is an enlarged view of the encircled portion of FIG. 4A.

FIG. 5 is a diagram showing the expected direction of fumes according to the movement of the stage unit during laser cutting.

FIG. 6 is a cross-sectional view of a suction unit according to another embodiment of the invention.

FIG. 7 is a cross-sectional view of a suction unit according to another embodiment of the invention.

FIG. 8 is a conceptual diagram illustrating a control device of an air blower linked with an suction port of a suction unit according to an embodiment of the invention.

FIG. 9 is a signal timing illustrating an embodiment of a control method of the control device of the air blower of FIG. 8.

FIG. 10 is a plan view of a suction unit according to another embodiment of the invention.

FIG. 11 is a perspective view of the suction unit of FIG. 10.

FIG. 12 is a plan view showing a control method of the suction unit in response to the movement of the stage unit according to another embodiment of the invention.

FIG. 13 is an airflow simulation diagram of the suction unit of the system for manufacturing a display device according to an embodiment of the invention.

FIG. 14 is a conceptual diagram of a control unit of a system for manufacturing a display device according to an embodiment of the invention.

FIG. 15 is a diagram showing the configuration of the air blower operation setting of FIG. 14.

FIG. 16 is a flow chart showing a manufacturing method of a display device according to an embodiment of the invention.

FIG. 17 is a diagram showing the effects of a conventional example and an experimental example of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

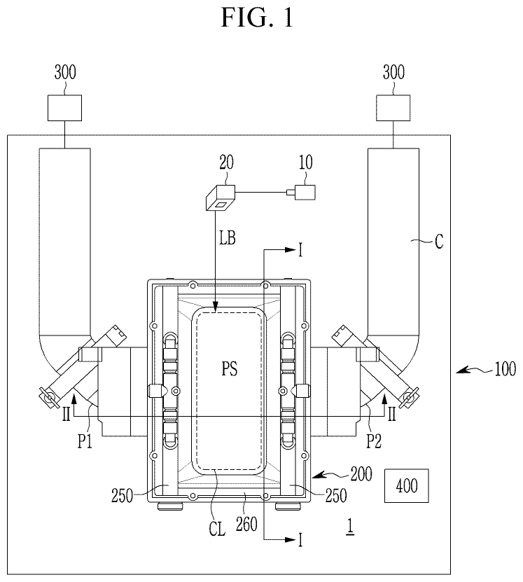

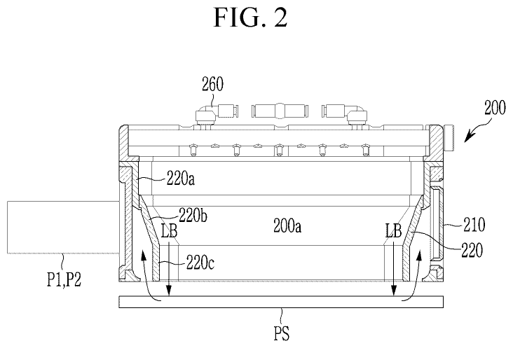

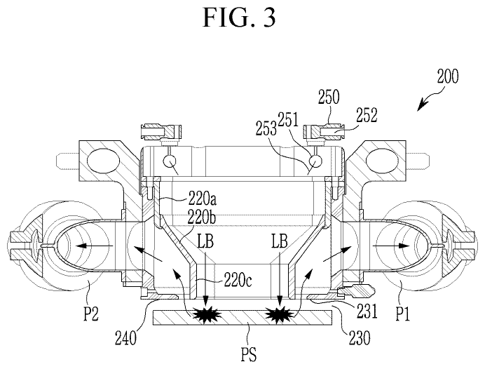

FIG. 1 is a plan view of a system for manufacturing a display device according to an embodiment of the invention, FIG. 2 is a cross-sectional view taken along line I-I of FIG. 1, and FIG. 3 is a cross-sectional view taken along line II-II of FIG. 1.

Referring to FIG. 1, a target substrate PS cut by the system for manufacturing a display device may be a display panel or a substrate of a display device such as an organic light emitting display device.

The system for manufacturing a display device may be used to cut an inspection pad for inspecting an organic light emitting display panel or to cut a protective film attached to protect the organic light emitting display panel.

The shape of the target substrate PS before cutting, which is shown by a dotted line in FIG. 1, may be a rectangular shape.

The four corners may be rounded, and may be cut using a laser beam along a closed curve-shaped cutting line CL to form a display device.

The cutting line CL may be an imaginary cutting line along which the laser beam LB is radiated on the target substrate PS.

However, the invention is not limited thereto, and an actual cutting line CL may be formed on the target substrate PS.

The cutting line CL may correspond to an edge of the display panel after cutting.

The target substrate PS before cutting may include a central portion disposed inside the cutting line CL and corresponding to the display panel DP after cutting, and an edge portion disposed outside the cutting line CL to become a dummy portion to be cut.

The system for manufacturing a display device according to an embodiment of the invention may be a device capable of cutting a target substrate PS by radiating a laser beam LB to the target substrate PS.

The system for manufacturing a display device 1 may include a laser module 10, an optical system 20, a stage unit 100, and a suction unit 200.

The laser module 10 may emit a laser beam LB.

The laser beam LB may be radiated along the cutting line CL of the target substrate PS. The laser module 10 may include a gas laser such as a carbon dioxide laser, an excimer laser, or a helium-neon laser, or a solid laser such as a ruby laser, a glass laser, a YAG laser, or a YLF laser.

The optical system 20 may adjust the path of the laser beam LB emitted from the laser module 10 to allow that the laser beam LB to be radiated to the target substrate PS.

The optical system 20 may include a homogenizer that homogenizes the shape of the laser beam LB and/or a condensing lens that focuses the laser beam LB.

The laser beam LB that passes through the optical system 20 may form a line beam.

Depending on the relative arrangement of the laser module 10 and the optical system 20, the optical system 20 may further include a mirror that changes the direction of the laser beam LB.

In an embodiment, for example, the optical system 20 may include a galvano scanner or a polygonal mirror.

The stage unit 100 provides a space on which the target substrate PS is seated and supports the target substrate PS.

That is, the target substrate PS may be seated on the stage unit 100.

The stage unit 100 may be provided with a suction hole (not shown) defined in an upper surface thereof and opened upward.

The stage unit 100 may fix the target substrate PS by providing negative pressure through the suction hole (not shown).

The target substrate PS may be generally placed in the center of the stage unit 100, but is not limited thereto.

The suction unit 200 may be located above the stage unit 100.

When the laser beam LB is radiated along the cutting line CL of the target substrate PS, fumes (i.e., smoke or gases) may be generated, and the suction unit 200 may suck up the fumes and discharge the fumes to the outside.

More detailed features of the suction unit 200 will be described later.

The system for manufacturing a display device according to an embodiment of the invention may further include a dust collection unit 300 and a control unit 400.

The dust collection unit 300 may be connected to the suction unit 200 by a connector C.

The dust collection unit 300 may collect fumes sucked by the suction unit 200.

The dust collection unit 300 may include a motor, a pump, or a fan for adjusting the negative pressure provided through the suction unit 200.

However, the invention is not limited thereto, and a motor, a pump, or a fan may be provided as a separate component from the dust collection unit 300.

The dust collection unit 300 may include a filter to filter out fumes.

The control unit 400 may control the characteristics of the laser beam LB generated by the laser module 10, the pressure provided by the dust collection unit 300, etc.

Referring to FIGS. 2 and 3, the suction unit 200 may include main bodies 210 and 220, pipes P1 and P2, a connection pipe C, and air blowers 250 and 260.

The pipes P1 and P2 are disposed on both opposing sides of the main bodies 210 and 220, the connector C connects the pipes P1 and P2 and the dust collection unit 300 to each other, and air blowers 250 and 260 are connected to the main bodies 210 and 220, and may be placed on the upper side of the main bodies 210 and 220.

The main bodies 210 and 220 may include an outer box 210 having open upper and lower sides and an inner cup 220 disposed within the outer box 210.

The inner cup 220 may be provided with upper and lower openings corresponding to the upper and lower openings of the outer box 210, respectively.

The main bodies 210 and 220 may trap fumes generated during the cutting process inside and effectively prevent the fumes from escaping to the outside.

The main bodies 210 and 220 may have a structure that is open on the upper and lower sides such that the laser beam LB coming out through the optical system 20 is radiated to the target substrate PS and has an empty internal space 200a.

Additionally, the main bodies 210 and 220 may have a structure that can effectively absorb fumes generated during the cutting process.

Hereinafter, the detailed structures of the outer box 210 and the inner cup 220 according to an embodiment will be described.

The outer box 210 may have a generally square pillar shape, but is not limited thereto, and may have a polygonal pillar or cylindrical shape other than a square pillar.

In an embodiment, the outer box 210 may have a rectangular pillar shape.

The outer box 210 has a hollow interior and can accommodate the inner cup 220.

Pipes P1 and P2 communicating with the interior of the outer box 210 may be coupled or formed on at least one side of the outer box 210.

The inner cup 220 may be placed within the outer box 210.

The inner cup 220 may include an upper side wall 220a in the shape of a rectangular pillar with an empty inside (or inner space), an inclined side wall 220b in the shape of a truncated square pyramid with an empty inside, and a lower side wall 220c in the shape of a square pillar with an empty inside.

The inner cup 220 may be separated (or separable) from the outer box 210.

The inner cup 220 may have a three-dimensional structure similar to a square funnel or hopper.

The inner cup 220 may have a shape corresponding to the shape of the outer box 210.

In an embodiment, for example, where the outer box 210 has a cylindrical shape, the inner cup 220 may have a three-dimensional structure similar to a circular funnel.

The inner space of the inner cup 220 may provide a passage through which the laser beam LB passes.

The laser beam LB may pass through the main bodies 210 and 220 and be radiated to the target substrate PS along the cutting line CL of the target substrate PS.

Accordingly, the cutting line CL of the target substrate PS may be disposed inside the lower opening of the main bodies 210 and 220 in a plan view.

The upper side wall 220a, the inclined side wall 220b, and the lower side wall 220c of the inner cup 220 may be formed integrally with each other as a single unitary indivisible part, or at least a portion may be formed separately and assembled.

However, the inner cup 220 is not limited to this, and the inclined side wall 220b and the lower side wall 220c may be formed integrally with each other as a single unitary indivisible part, the upper side wall 220a is formed separately, and the inclined side wall is formed at the lower part of the upper side wall 220a. The upper part of 220b may be joined thereto.

The upper opening of the main bodies 210 and 220 can be defined by the upper part of the upper side wall 220a of the inner cup 220, and the lower opening of the main bodies 210 and 220 can be defined by the lower part of the lower side wall 220c of the inner cup 220.

The upper opening of the bodies 210 and 220 may be larger than the lower opening in the plan view.

Accordingly, the inclined side wall 220b may have a structure in which the internal width decreases from the upper side wall 220a to the lower side wall 220c.

That is, the internal structure of the inclined side wall 220b may have a funnel-like structure in which the internal width gradually decreases as being towards the lower side wall 220c.

Accordingly, the downflow effect may be maintained inside the inner cup 220, such that fumes may be sucked in smoothly.

The outer surface of the upper side wall 220a may be in close contact with the inner surface of the outer box 210.

The suction unit 200 may further include a bracket for securing the inner cup 220, and a lower plate 240 defining a suction port 230 with the inner cup 220 and defining an exhaust path PL with the outer box 210 and the inner cup 220.

The lower plate 240 may be coupled to the bottom of the outer box 210.

The lower plate 240 may be coupled to the bottom of the outer box 210 by coupling units such as screws or a slide insertion method.

The lower plate 240 may define a through hole extending through the interior.

The through hole of the lower plate 240 may be larger than the lower opening of the inner cup 220.

The lower plate 240 is an end portion defining the through hole and may include a suction end 231 surrounding the through hole.

The suction end 231 may overlap the lower end of the lower side wall 220c of the inner cup 220.

The suction end 231 and the lower end of the lower side wall 220c of the inner cup 220 may define the suction port 230.

Fumes may be sucked into the suction unit 200 from the outside through the suction port 230.

The suction port 230 may be disposed around the lower end of the lower side wall 220c of the inner cup 220.

The suction port 230 may be open in a vertical direction, but is not limited thereto.

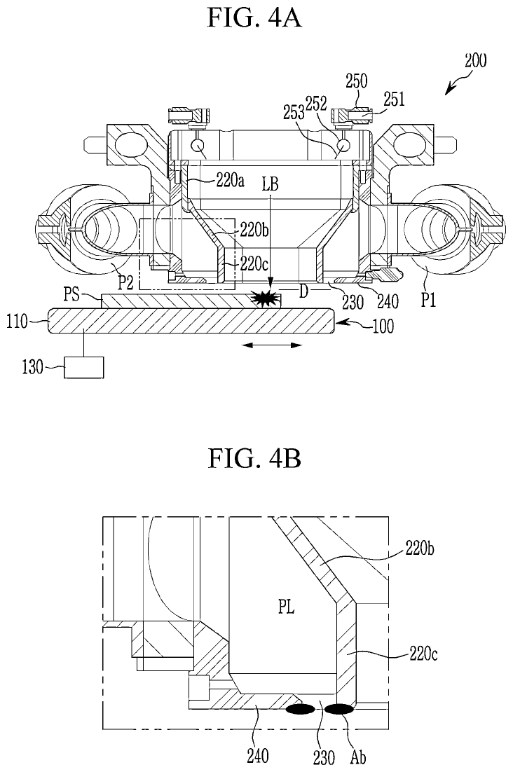

The upper surface of the lower plate 240, the inner surface of the outer box 210, and the outer surface of the inner cup 220 (particularly, the outer surfaces of the inclined side wall 220b and the lower side wall 220c) may define an exhaust path PL (shown in FIG. 4B).

The exhaust passage PL may be a space in which fumes sucked through the suction port 230 flow inside the main bodies 210 and 220.

The exhaust passage PL may be substantially sealed except for the portion opened for communicating with the pipes P1 and P2 and the suction port 230.

Therefore, most of the fumes sucked through the suction port 230 may move to the pipes P1 and P2 through the exhaust path EP.

Fumes that have moved to the pipes P1 and P2 may be collected in the dust collection unit 300 through the connection pipe C.

Air blowers 250 and 260 may be disposed on top of the main bodies 210 and 220.

The air blowers 250 and 260 may spray air toward the target substrate PS.

Air provided by the air blowers 250 and 260 may form an airflow in the inner space of the inner cup 220.

The air blowers 250 and 260 may include a pair of first air blowers 250 arranged along the long side of the outer box 210 and a pair of second air blowers 260 arranged along the short side.

The first air blowers 250 may be arranged to face each other along the long side of the outer box 210.

The first air blower 250 may include a first main pipe 251, a plurality of first nozzles 253 disposed at a lower end of the first main pipe 251 and arranged along a first direction, and a first auxiliary pipe 252 disposed at an upper end of the first main pipe 251.

The first main pipe 251 may be a pipe extending along the first direction and including an internal flow path.

The first main pipe 251 may be arranged along the long side of the outer box 210.

The first main pipe 251 provides a space to accommodate air before it is sprayed through the first nozzle 253, and the space to accommodate air may be an internal flow path of the first main pipe 251.

The air accommodated in the inner flow path of the first main pipe 251 may be supplied from the first auxiliary pipe 252 located on the upper side and can be sprayed into the inner space of the inner cup 220 through the first nozzle 253 located on the lower side.

The direction of air injection may be substantially the same as the direction indicated by the first nozzle 253.

Air injected through the first nozzle 253 may form an airflow in the injection direction.

The first nozzle 253 may be a passage through which air contained inside the first main pipe 251 is sprayed to the outside.

The plurality of first nozzles 253 may be arranged along the extension direction of the first main pipe 251 at the lower part of the first main pipe 251.

The first nozzle 253 may extend in a direction perpendicular to the first main pipe 251.

The slope of the first nozzle 253 may change.

The inclination of the first nozzle 253 may be defined as an angle at which the first nozzle 253 is inclined with respect to a plane parallel to one surface of the target substrate PS.

The injection angle of the air sprayed from the first nozzle 253 may be substantially the same as the inclination of the first nozzle 253.

The first nozzle 253 may have an adjustable inclination, but is not limited to this and may have a fixed inclination.

In an embodiment, the inclination of the first nozzle 253 may be set in a way such that air sprayed from the first nozzle 253 crosses the inner space of the inner cup 220.

The first nozzle 253 may be directed toward the suction port 230 disposed on the lower side of the first air blower 250 opposite to the first air blower 250 including the first nozzle 253.

Accordingly, the airflow formed by the air injected from the first nozzle 253 may be sucked into the suction port 230 disposed on the opposite side of the first nozzle 253.

Additionally, airflows formed by each air injected from the first nozzles 253 disposed opposite to each other may intersect in the inner space of the inner cup 220, but are not limited thereto.

Hereinafter, with reference to FIGS. 4 to 17, the system and method for manufacturing the display device according to an embodiment of the invention for responding to fume movement due to external air current changes when the stage unit 100 moves.

FIG. 4A is a diagram showing a system for manufacturing a display device according to an embodiment of the invention, and FIG. 4B is an enlarged view of the encircled portion of FIG. 4A.

The system for manufacturing a display device for a display device according to an embodiment of the invention includes a stage unit 100 including a base substrate 110 on which a substrate or a panel PS of the display device to be laser cut is arranged, respectively, and a stage drive 130 (e.g., an UVW driver) for high-precision, high-response positioning of the base substrate 110 in the X-axis, Y-axis, and θ-direction. In such an embodiment, the stage unit 100 is substantially the same as the stage unit in the manufacturing system 1 of a display device shown in FIG. 1, except that the laser module 10 and the optical system 20 are fixed, and the stage unit 100 is moved in the X-axis, Y-axis, and θ-directions to perform the laser cutting process of the substrate or the panel PS of the display device.

In an embodiment, as shown in FIG. 4A, a target substrate PS is placed on the stage unit 100, and the laser beam LB is radiated for at least one cycle along the cutting line CL of the closed curve to cut the target substrate PS, and when the laser beam LB is radiated to cut the target substrate PS, so that the laser beam LB is not obscured by the fumes generated in the area where the laser beam LB is radiated, the fumes can be sucked in and effectively discharged to the outside through the negative pressure provided by the dust collection unit 300.

Specifically, fumes can be inhaled through the suction port 230 of the suction unit 200.

The suction port 230 is provided or defined at the lower part of the suction unit 200 and may have a shape that opens downward.

The suction port 230 may be disposed outside the cutting line CL.

The suction port 230 may not overlap the cutting line CL of the target substrate PS, but is not limited thereto.

Air can be sprayed through the air blowers 250 and 260 to form an airflow that can move fumes to the outside of the cutting line CL.

However, even if the fumes move outside the cutting line CL, most of the fumes are sucked in through the suction port 230 of the suction unit 200, such the fumes may hardly leak out of the suction unit 200.

However, as shown in FIG. 4A, when a target substrate PS is placed on the stage unit 100, and the base substrate 110 of the stage unit 100 is moved using the stage drive unit 130 while the laser beam LB is in a fixed state to move the target substrate PS to allow the laser beam LB to be radiated along the cutting line, the suction force may decrease as a distance D between the location where the laser beam LB is radiated to perform the laser cutting and the suction port 230 increases.

In such an embodiment, if the suction power of the suction unit 200 is reduced as the distance D increases, an amount of the fumes remaining in the internal space 200a may increase and the optical system 20 may be contaminated by the fumes.

In such an embodiment, the substrates or panels of the display device are multilayered, including adhesive components, such as pressure sensitive adhesive (PSA) Ab, between the layers. In the case of fumes generated when laser cutting the substrates or panels PS of the display device containing the adhesive component (PSA), the suction port 230 may become gradually narrow and blocked due to the adhesive component sticking around the suction port 230, as shown in FIG. 4B.

In such an embodiment, if the suction port 230 becomes narrower or blocked due to the adhesive component of fumes generated during laser cutting of the panel PS, the suction performance of the suction unit 200 may deteriorate.

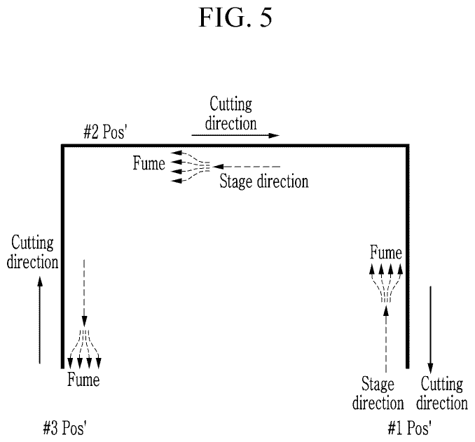

FIG. 5 is a diagram showing the expected direction of fumes according to the movement of the stage unit during laser cutting.

As shown in FIG. 5, according to the system for manufacturing a display device 1′ according to an embodiment of the invention, when the base substrate 110 of the stage unit 100 is moved using a stage driver 130, the base substrate 110 moves from the first position (#1 Pos′) in the first direction to the second position (#2 Pos′), the base substrate 110 moves from the second position (#2 Pos′) in the second direction perpendicular to the first direction to the third position (#3 Pos′), which is opposite to the first direction, such that the direction in which the laser beam LB is radiated and laser cutting is performed is opposite to the first, second, and third directions. In this case, as shown in FIG. 5, the fumes are generated by the laser cutting in the forward direction with respect to the first, second, and third directions of the stage unit 100.

According to the system for manufacturing a display device 1′ according to an embodiment of the invention, the fumes may not be completely removed (or sucked) due to the moving speed of the stage unit 100 and the moving direction of stage unit (or the fumes), and the fumes may remain internally or leak to an outside such that the optical system 20 or an surrounding equipment may be contaminated.

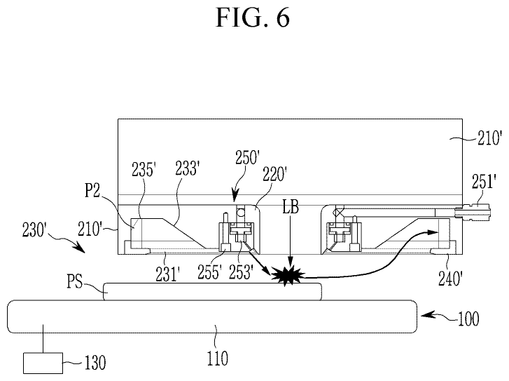

FIG. 6 is a cross-sectional view of a suction unit according to an embodiment of the invention.

The suction unit 200′ according to an embodiment of the invention can control fumes generated during laser cutting processing of the substrate or the panel PS of the display device while moving the stage unit 100. Such an embodiment of the suction unit 200′ may has an improved configuration in a structure disposed at the lower part of the outer box 210′ and the inner cup 220′.

The suction unit 200′ according to an embodiment of the invention may effectively prevented fumes from being accumulated in the suction port 230 due to the moving speed of the stage unit 100 and the moving direction of the stage unit 100 (or the fumes), or from being exposed to the optical system 20 or the outside.

In such an embodiment, the suction port 230′ is provided with a through hole in the lower plate 240′ so that the entire portion of the fumes generated during laser cutting processing can be sucked in response to the moving speed of the stage unit 100 and the moving direction of the stage unit 100 (or the fumes). In such an embodiment, the suction port 230′ may be provided with an expansion hole 231′ formed widely, and may include a guide portion 233′ inclined upward and outward at the edge of the lower plate 240′ to form the expansion hole 231′ with the lower plate 240′, and an eddy forming portion 235′ extending parallel to the lower plate 240′ to prevent the fumes sucked through the expansion hole 231′ from being exposed to the outside when negative pressure is formed during operation of the dust collection unit 300.

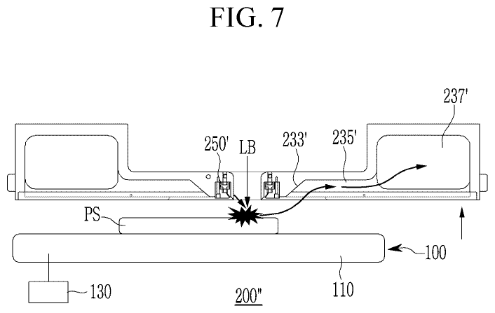

FIG. 7 is a cross-sectional view of a suction unit according to another embodiment of the invention.

The suction unit 200′, according to another embodiment the invention, has an expansion hole 231′ to prevent fumes from accumulating in the inlet 230 or from being exposed to the optical system 20 or to the outside depending on the speed of movement of the stage unit 100 and the direction of movement of the fumes. In such an embodiment, the suction unit 200′ includes an inlet 230′ having a guide portion 233′ and an eddy forming portion (or hump-shaped portion) 235′ as similarly to the suction unit shown in FIG. 6, and may further includes a fume storage cavity 237′ extending from the hump-shaped portion 235′ of the inlet 230′ for temporarily storing fumes collected by negative pressure and blocking leakage to the outside.

In such an embodiment, the suction unit 200′ includes air blowers 250′ and 260′ between the internal space 200 where the laser beam LB is radiated and the fume storage cavity 237′ on all sides of the target substrate PS along the line CL.

The fume storage cavity 237′ sufficiently stores the fume eddies quickly introduced through the expansion hole 231′ by the air blowers 250′ and 260′ to store the fumes, thereby effectively blocking the fumes from being exposed to the optical system 20 or the outside.

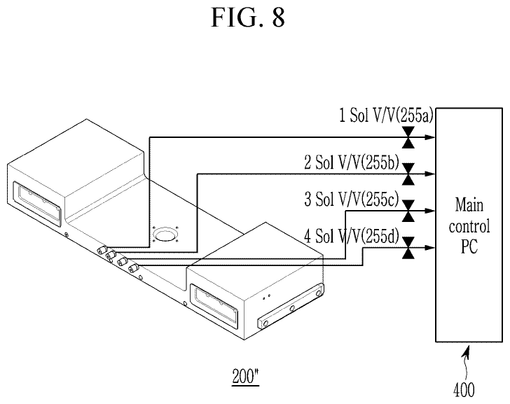

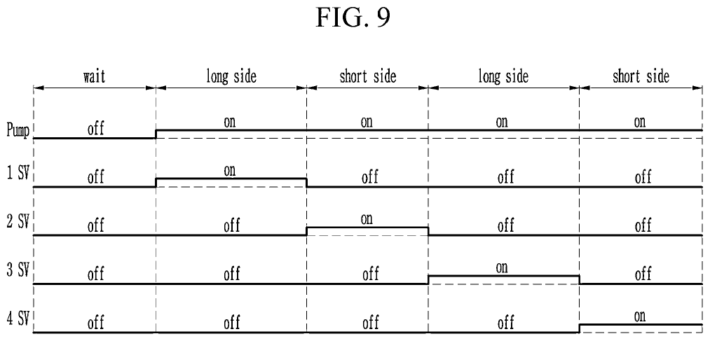

FIG. 8 is a conceptual diagram illustrating a control device of an air blower linked with a suction port of a suction unit according to an embodiment of the invention, and FIG. 9 is a signal timing illustrating an embodiment of a control method of a control device of the air blower of FIG. 8.

In an embodiment, as shown in FIGS. 6 to 8, the suction port 230′ of the suction unit 200′ according to an embodiment of the invention′ may be controlled by the control unit 400 to link with an air blower 250′ that blows air directly toward the air suction port 230′ at a height close to the suction port 230′.

In an embodiment, as shown in FIG. 8, the control unit 400 can receive information on the movement speed and direction of the stage unit 100, and control the on-off time of the first to fourth solenoid valves (255a, 255b, 255c, 255d) of a pair of air blowers 250′ positioned on the long sides and a pair of air blowers 260′ positioned on the short sides of the edges surrounding the internal space 200a where laser cutting takes place, so that the distance value (D) from the cutting line CL remains constant.

A pair of air blowers 250′ arranged on the long side are referred to as the first air blowers 250′, and a pair of air blowers 260′ arranged on the short side are referred to as the second air blowers (250′, 260′), where the first and second air blowers 250′ and 260′ are similarly disposed in the first main pipe 251′ and below the first main pipe 251′ and are arranged along the first direction, and the first and second air blowers 250′ may include a plurality of first nozzles 253′ and a first auxiliary pipe 252′ disposed on the upper part of the first main pipe 251′, and include the first to fourth solenoid valves 255a, 255b, 255c and 255d installed in the first main pipe 251′ to control the opening and closing of the plurality of first nozzles 253′, respectively.

The first air blower 250′ and the second air blower 260′ differ from the first air blower 250 and the second air blower 260 in that the first main pipe 251′ is an external box, it is installed through the lower part of 210′, and the first nozzle 253′ may be installed between the suction inlet unit 230′ and the internal space 200a where laser cutting is performed.

As shown in FIG. 9, negative pressure is formed by the dust collection unit 300 during the laser cutting process, that is, not at the air blowers 250′ and 260′ close to the operating suction port 231′, but at the opposing air blowers 250′ and 260′. The air blowers 250′ and 260′) at distant locations can be operated selectively.

In more detail, in the standby mode, the pump and the 1st to 4th solenoid valves (255a, 255b, 255c, 255d) are turned off, the first solenoid valve (255a) of the first air blower 250′ installed in the second long valve is turned on to use the intake 231′ of the first long valve, the second solenoid valve (255b) of the second air blower (260′) installed in the second short valve is turned on to use the intake (231′) of the first short valve, the third solenoid valve (255c) of the first air blower (250′) installed in the first long valve is turned on to use the intake (231′) of the second long valve, and the fourth solenoid valve (255d) of the second air blower (260′) installed in the first short valve is turned on to use the intake (231′) of the second short valve, as shown in FIG. 9.

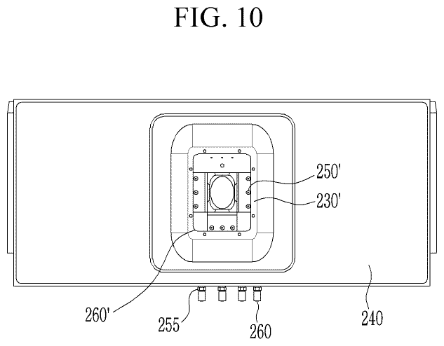

Now, with reference to FIGS. 10 to 12, a suction unit according to another embodiment of the invention will be described in more detail.

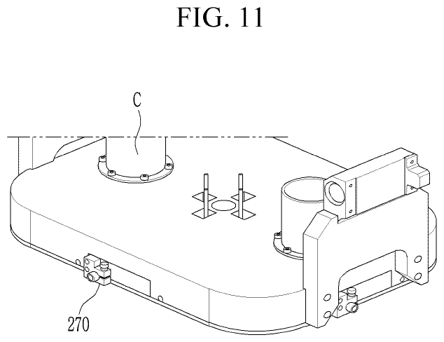

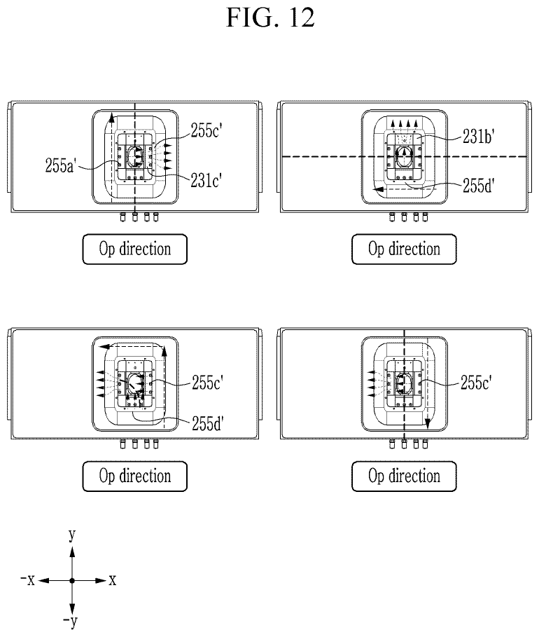

FIG. 10 is a plan view of a suction unit according to another embodiment of the invention, FIG. 11 is a perspective view of the suction unit of FIG. 10, and FIG. 12 is a plan view showing an embodiment of the control method of the suction unit in response to the movement of the stage unit.

As shown in FIG. 10, the air injection direction of the first air blower 250′ and the second air blower 260′ is generally the same as the direction indicated by the first nozzle 253′, and the air injected through the first nozzle 253′ may form an airflow in the injection direction.

The first nozzle 253′ may be a passage through which air contained within the first main pipe 251′ is sprayed to the outside.

The plurality of first nozzles 253′ may be arranged along the extension direction of the first main pipe 251′ at the lower part of the first main pipe 251′.

The first nozzle 253′ may extend in a direction perpendicular to the first main pipe 251′.

In an embodiment, as described above, the slope of the first nozzle 253′ may change.

As shown in FIG. 10, the injection angle of the air sprayed from the first nozzle 253′ may be substantially the same as the inclination of the first nozzle 253′, and the inclination of the first nozzle 253′ is the injection angle, and can be adjusted by the angle adjustment unit 260.

As shown in FIG. 11, the spraying position of the first nozzle 253′ arranged along the extension direction of the first main pipe 251′ may be adjusted, and the position of the first nozzle 253′ may be adjusted along the long side or along the short side, respectively, by the spraying adjustment unit 270 installed at the lower end of the outer box 210′ of the suction unit 200′.

FIG. 12 is a diagram showing the on and off of the air blower in response to the moving direction of the stage unit.

In FIG. 12, the dotted line is the laser cutting line, the dotted arrow indicates the stage movement direction, and the arrows inside the laser work hole indicate the air injection direction and the fume movement direction when the air blower operates.

As shown in FIG. 12, when the stage unit 110 moves in the y direction and laser cutting is performed in the long side direction, the first solenoid valve 255a′ of the suction unit 200′ is opened, and when the first solenoid valve 255a′ is opened, the air sprayed from the first air blower 250′ by spraying air toward the second suction port 231c′ opposite to first solenoid valve 255a′ is generated in the long side area of the cutting line CL of the target substrate PS, fumes can be moved toward the second suction port 231a′.

When the stage unit 110 moves in the −x direction and laser cutting occurs in a unidirectional manner, the fourth solenoid valve 255d′ of the suction unit 200′ opens, and air is sprayed towards the third suction port 231b′ facing the fourth solenoid valve 255d′, and the air sprayed from the second air blower 260′ can move the fumes generated in the unidirectional area of the cutting line CL of the target substrate PS towards the third suction port 231b′.

When the stage unit 110 moves in the y direction and laser cutting is performed in the long side direction, the first solenoid valve 255c′ of the suction unit 200′ is opened, and the second solenoid valve 255a′ opposite the first solenoid valve 255c′ is opened, and the air sprayed from the first air blower 250′ removes the fumes generated in the long side area of the cutting line CL of the target substrate PS to the second air blower 250′ by spraying air toward the suction port 231a′, so the fumes can be moved toward the suction port 231a′.

In such an embodiment, after the stage unit 110 is moved in the y direction, such as at a corner, when laser cutting of the corner is performed while moving the stage unit 110 in the −x axis direction, after the stage unit 110 is moved in the y direction, the air blown from the first air blower 250′ and the second air blower 260′ can move the fumes generated in the corner region of the cutting line CL of the target substrate PS using the third and fourth inlets by opening the third solenoid valve 255c′ and the fourth solenoid valve 255d′ together in consideration of the direction of the fumes generated by moving the stage unit 110 in the −x axis direction.

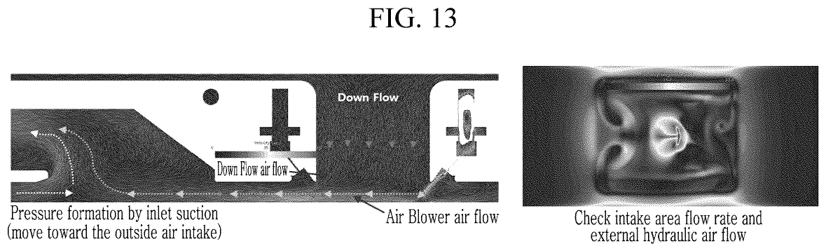

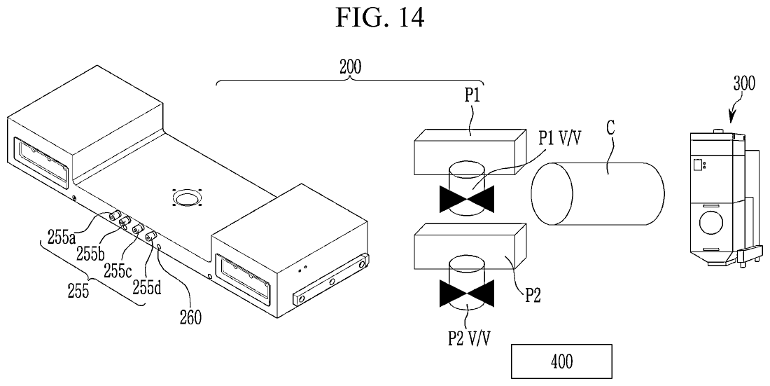

Hereinafter, with reference to FIGS. 13 and 14, how the suction unit of the system for manufacturing a display device according to an embodiment of the invention interlocks the suction port 230′ and the air blowers 250′ and 260′ to create a predetermined airflow, and to completely remove fumes by forming the predetermined airflow will be described.

FIG. 13 is an airflow simulation diagram of a suction unit of a system for manufacturing a display device according to an embodiment of the invention, and FIG. 14 is a conceptual diagram of a control unit of a system for manufacturing a display device according to an embodiment of the invention.

As shown in FIG. 13, in which the simulation of the airflow that occurs when laser cutting processing is performed in the manufacturing system of the display device according to an embodiment of the invention is shown, in the internal space 200a where the laser beam LB is radiated in the downflow, when at least one of the first air blower (250′) and the second air blower (260′) arranged in all directions in close proximity to the laser cutting part where laser cutting processing is performed for the downflow is opened, it can be seen that the downflow is biased and moves toward at least one inlet where negative pressure is generated among the first to fourth inlets by the dust collection unit 300.

In addition, as a result of simulating the change in flow rate in at least one inlet area where negative pressure is formed among the first to fourth inlet ports, it was confirmed that external airflow was introduced.

As shown in FIG. 14, in the system for manufacturing a display device according to an embodiment of the invention, the control unit 400 is the suction unit 200 of the system for manufacturing a display device according to an embodiment of the invention, and the air injection position can be adjusted by turning the first to fourth solenoid valves 255a, 255b, 255c, and 255d of the first air blower 250′ and the second air blower 260′, respectively, on and off, the angle of the injection nozzle 253 can be adjusted.

In addition, the control unit 400 is capable of controlling the negative pressure of the first and second connection pipes P1 and P2 of the suction unit 200 connected to the connection pipe C of the dust collection unit 300, and is an aspect of the invention, so the piping pressure of the first and second connection pipes P1 and P2 connected to the suction unit 200 of the system for manufacturing a display device according to an embodiment can be adjusted by the pipe pressure control valves (P1V/V, P2V/V).

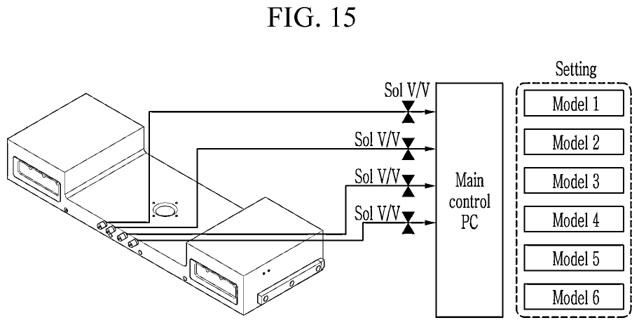

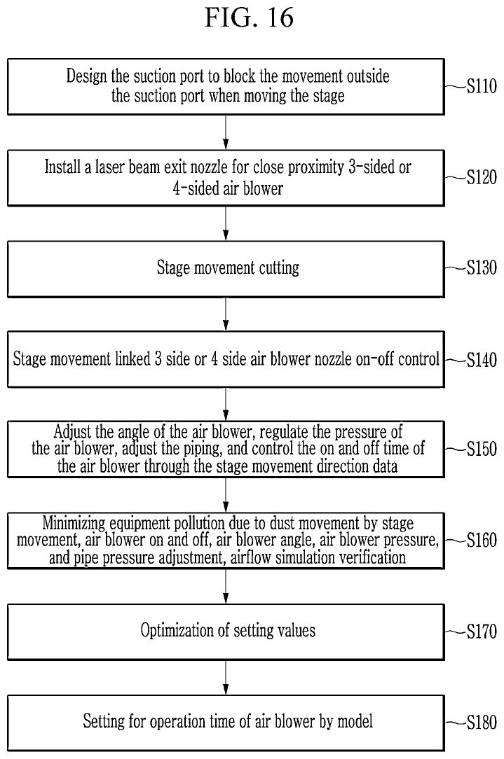

FIG. 15 is a diagram illustrating an air blower operation setting of a control unit of a display manufacturing system according to an embodiment of the invention, and FIG. 16 is a flowchart illustrating a method of manufacturing a display according to an embodiment of the invention.

As shown in FIGS. 15 and 16, the control unit 400 of the system for manufacturing a display device according to an embodiment of the invention causes fumes to be emitted from the work object, for example, the display panel, when the stage unit 110 is moved. An inlet structure is designed based on airflow simulation to block movement of the fumes to outside the inlet 230 formed around all sides of the target substrate PS (S110).

In an embodiment, an air blower (250′, 260′) is installed on three or four sides close to the laser cutting end where the laser beam LB flows in and laser cutting is performed (S120), and the laser is cut while moving the stage unit 110. While cutting (S130), the first to fourth solenoid valves (255a, 255b, 255c, 255d) of the air blowers (250′, 260′) installed on three or four sides in conjunction with the movement of the stage unit 110 may be controlled to be on and off (S140).

The air injection position can be adjusted by turning the first to fourth solenoid valves 255a, 255b, 255c, and 255d of the first air blower 250′ and the second air blower 260′, respectively, on and off, the angle of the spray nozzle 253 can be adjusted, and the negative pressure of the first and second connection pipes (P1, P2) of the suction unit 200 connected to the connection pipe (C) of the dust collection unit 300 can be adjusted, the pipe pressure of the first and second connection pipes (P1, P2) connected to the suction unit 200 of the system for manufacturing a display device according to an embodiment of the invention is controlled by pipe pressure control valves (P1V/V, P2V/V), on and off the on-off time of the air blower (250′, 260′) is controlled through the moving direction data of the stage unit 140 (S150).

To minimize contamination of the optical system or an external equipment due to fume movement by the stage unit 110, the on/off and angle of the first air blower (250′) and the second air blower (260′) may be determined based on the air flow simulation while adjusting the air pressure and piping pressure (S160).

Depending on the size or specifications of the work object, such as the display panel PS, the first to fourth solenoid valves 255a, 255b, 255c, and 255d of the first air blower 250′ and the second air blowers (260′ 255d) setting values for on-off and time are optimized (S170) and stored in the memory unit of the control unit 400 to create a setting for air blower operation and time for each display panel PS model (S170).

As shown in FIGS. 15 and 16, according to the method of manufacturing a display device according to an embodiment of the invention, the display panel PS is processed through laser cutting according to the model of the work object, for example, the display panel PS, the on/off state of the first to fourth solenoid valves 255a, 255b, 255c, and 255d of the air blowers (250′ and 260′) disposed on all sides around the display panel PS so as to face the suction ports formed in a closed curve shape, by changing the setting values of the off and on-off operation times, the setting values for each model can be optimized, and the air blower (250′, 260′) can be adjusted according to the model of each work object, such as the display panel PS, by creating a recipe, so each operation time can be optimized.

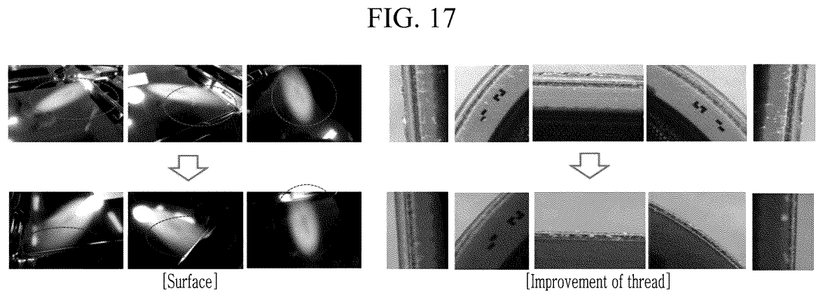

FIG. 17 is a diagram showing the effects of a conventional example and an experimental example of the invention.

As can be seen through FIG. 17, according to the conventional method of manufacturing a display device, when the air blowers 250 and 260 are not used or are not controlled on/off, the target substrate PS using the laser beam LB during the cutting process, it can be seen that fumes generated along the cutting line CL block the laser beam LB and interfere with processing of the target substrate PS, leaving particles or threads formed on the surface of the target substrate PS.

On the other hand, according to the method of manufacturing a display device according to an experimental example of the invention, the on-off control and on-off operation time of the air blowers 250′ and 260′, which are controlled in conjunction with the movement of the stage unit 110, are controlled by the controlled air, the fumes generated from the target substrate PS are generally generated and simultaneously descend by the downflow formed in the internal space of the inner cup 220 and the suction unit 200, so it was confirmed that almost no particles remained on the surface of the target substrate PS as it was sucked out and removed through the suction port 230′ and that the thread texture was also improved.

According to the system and method for manufacturing a display device according to an embodiment of the invention, the quality and improvement of the display device are secured by controlling the fumes generated when moving the stage, on which the panel of the display device is placed, in the laser cutting device of the display device.

According to the system and method for manufacturing a display device according to an embodiment of the invention, it is possible to prevent equipment contamination due to fume movement due to stage movement, e.g., contamination of the exterior or optical system, based on air flow simulation, for example.

According to the system and method for manufacturing the display device according to an embodiment of the invention, clogging of the suction port by fumes containing adhesive components can be minimized through optimal design of the suction port, thereby increasing the maintenance period of the suction unit.

According to the system and method for manufacturing a display device according to an embodiment of the invention, the operation of a plurality of air blowers disposed on all sides of the suction unit is controlled on and off, and the operation is turned on and off at a time based on the laser cutting line length for each target substrate model, so the setting values can be fed back into a setting by linking target substrate models with the movement of the stage unit.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A system for manufacturing a display device, the system comprising:
a main body which is open on upper and lower sides and forms an internal space through which a laser beam from an optical system is radiated to a target substrate;
an exhaust passage provided between an upper surface of a lower plate of the main body, an inner surface of an outer box of the main body, and an outer surface of an inner cup of the main body surrounding a cutting line of the target substrate;
a stage unit, on which the target substrate is placed, wherein the stage unit moves in way such that the laser beam is radiated along the cutting line of the target substrate which moves with the stage unit;
a suction unit which suctions fumes generated during a laser beam radiation processing on the target substrate while moving the stage unit; and
a control unit which controls a setting value of the suction unit based on a moving speed of the stage unit and a moving direction of the stage unit.

2. The system for manufacturing a display device of claim 1, wherein
the suction unit includes a suction port connected to the exhaust passage, and
the suction port includes an expansion hole which is open with respect to the lower plate across the inner cup and the outer box.

3. The system for manufacturing a display device of claim 2, wherein
the suction port includes a guide part inclined upward and outward at an edge of the expansion hole, and an eddy forming portion to form an eddy for the fumes sucked through the expansion hole by negative pressure generated when a dust collection unit connected to the exhaust passage operates.

4. The system for manufacturing a display device of claim 3, wherein
the suction unit include a fume storage cavity extending from the eddy forming portion to store the fumes collected through the expansion hole and block leakage of the fumes to an outside.

5. The system for manufacturing a display device of claim 2, further comprising:
an air blower disposed between the expansion hole and the internal space at a lower part of the main body adjacent to the suction port, wherein the air blower forms a lateral airflow to move the fumes toward the suction port.

6. The system for manufacturing a display device of claim 5, further comprising:
an air blower including a pair of first air blowers disposed on a long side of sides surrounding the internal space and a pair of second air blowers disposed on a short side of the sides,
the control unit receives information on the moving speed and the moving direction of the stage unit, and
the control unit independently controls on and off of first to fourth solenoid valves installed in the first and second air blowers.

7. The system for manufacturing a display device of claim 6, wherein each of the first and second air blowers comprises:
a first main pipe installed through a lower part of the outer box of the main body; and
a first nozzle attached to the first main pipe, and
wherein the first to fourth solenoid valves control on and off of the first nozzle.

8. The system for manufacturing a display device of claim 7, further comprising:
a spray angle control unit which adjusts a tilt of the first nozzle; and
a spray position control unit which adjusts the spray position of the first nozzle.

9. A method of manufacturing a display device, the method comprising:
controlling an on and off operation time of an air blower based on a movement of a stage unit,
wherein an inlet, through which fumes generated by a target substrate processed by laser beam radiation are sucked up, and a hovering forming portion through which the fumes are allowed to hover therein are disposed in an inner space of a main body, through which a laser beam is radiated, and
the air blower is disposed between the inlet and the inner space in the main body to form an air to flow through the inlet.

10. A suction unit comprising:
a suction port connected to an exhaust passage;
an air blower which forms an airflow to move fumes generated when cutting a target substrate by radiating a laser beam toward the suction port, wherein the air blower is disposed at a lower part of a main body which is close to the suction port between the suction port and an inner space of the main body through which the laser beam is radiated; and
a control unit which controls the air blower in a way such that the fumes are sucked into the suction port in response to a moving speed of the stage unit and a moving direction of the stage unit.

11. The suction unit of claim 10, wherein
the suction port includes an expansion hole formed open across an inner cup and an outer box of the main body.

12. The suction unit of claim 11, wherein
the suction port has a guide part inclined upward and outward at an edge of the expansion hole, and an eddy forming portion extending from the guide part, wherein the eddy forming portion forms an eddy of the fumes sucked through the expansion hole by negative pressure generated when a dust collection unit connected to the exhaust passage operates.

13. The suction unit of claim 12, further comprising:
a fume storage cavity extending from an end of the eddy forming portion to store the fumes collected through the expansion hole and block leakage of the fumes to an outside.

14. The suction unit of claim 13, further comprising:
an air blower including a pair of first air blowers disposed on a long side of sides surrounding the inner space, and a pair of second air blowers disposed on a short side of the sides,
wherein the control unit receives information on the moving speed and the moving direction of the stage unit, and
the control unit independently controls on and off of first to fourth solenoid valves installed in the first and second air blowers.

15. The suction unit of claim 14, wherein
each of the first and second air blowers includes a first main pipe installed through a lower part of an outer box of the main body, and a first nozzle attached to the first main pipe, and
each of the first to fourth solenoid valves turns the first nozzle on and off.

16. The suction unit of claim 15, further comprising:
a spray angle control unit which adjusts an inclination of the first nozzle; and
a spray position control unit which adjusts a spray position of the first nozzle.

17. A method of controlling a suction unit, the method comprising:
simulating an airflow about a suction port, through which fumes generated when a laser beam is radiated on a target substrate on a stage unit to cut the target substrate are sucked up;
installing an air blower on three or four sides around a laser cutting end at a height close to the suction port; and
controlling on and off of first to fourth solenoid valves of the air blower based on a movement of the stage unit while performing laser cutting on the target substrate while moving the stage unit.

18. The method of controlling the suction unit of claim 17, further comprising:
selectively controlling the on and off of the first to fourth solenoid valves of the air blower and adjusting a spraying position and a spraying angle of a nozzle of the air blower;
controlling a pipe pressure of first and second connection pipes, which are connected to a dust collection unit, by controlling pipe control valves of the first and second connection pipes; and
storing on-off operation and operation time data of the first to fourth solenoid valves in response to a moving speed and a moving direction of the stage unit,
where the simulating an airflow comprises adjusting the on and off of the first to fourth solenoid valves, the spray angle, an air pressure of the air blower, and the pipe pressure of the first and second connection pipes based on a movement of the fumes by the stage unit.

19. The method of controlling the suction unit of claim 18, further comprising:
optimizing on-off operation and on-off operation time setting values of the first to fourth solenoid valves of the air blower; and
creating a setting based on optimized setting values of the air blower for the target substrate.
